(19) United States
(12) Patent Application Publication
(10) Pub. No.: US 2015/0296158 A1
(43) Pub. Date: Oct. 15, 2015

(54) Reconfigurable CMOS Image Sensor

(71) Applicant: Forza Silicon Corporation, Pasadena, CA (US)

(72) Inventors: Barmak Mansoorian, La Canada Flintridge, CA (US); Shawn Maloney, San Francisco, CA (US)

(21) Appl. No.: 14/683,261

(22) Filed: Apr. 10, 2015

Related U.S. Application Data
(60) Provisional application No. 61/977,960, filed on Apr. 10, 2014.

(51) Int. Cl. H04N 5/374; H04N 5/225; H01L 27/146

(52) U.S. Cl. CPC H04N 5/374; H01L 27/14634; H01L 27/14636; H04N 5/2258

(57) ABSTRACT

CMOS image sensors are generally customized and designed for specific functions and capabilities. Chip layout design and the development of fabrication schemes are very expensive. This high non-recurring engineering cost presents a significant barrier to the development of chips performing new processing schemes, for example specialty chips for small markets. Accordingly, there is a need in the art for simplified means of providing customized image sensors. Disclosed herein are novel stacked image sensors comprising an image sensor wafer stacked on one or more customizable processing wafers. The processing wafer comprises one or more reconfigurable components that can be programmed and customized to perform a very broad set of operations, providing the art with a means of obtaining a customizable image sensor without the substantial non-recurring engineering costs encountered using current technologies. Reconfigurable components include ADC components, memory components, chip control components, data processing components, and I/O interface components.

### CROSS-REFERENCE TO RELATED APPLICATIONS

This application claims the benefit of priority to U.S. Provisional Patent Application Ser. No. 61/977,960 entitled “Reconfigurable CMOS Image Sensor,” filed Apr. 10, 2014, the contents of which are hereby incorporated by reference.

### REFERENCE TO SEQUENCE LISTING, A TABLE, OR A COMPUTER PROGRAM LISTING COMPACT DISK APPENDIX

Not Applicable.

### STATEMENT REGARDING FEDERALLY SPONSORED RESEARCH OR DEVELOPMENT

Not Applicable.

### BACKGROUND AND SUMMARY OF THE INVENTION

Stacked CMOS image sensor chips are known in the art. In a common configuration, a chip optimized for image sensing functions is stacked on top of another chip optimized for processing functions. Light capture, charge integration, pixel readout, and conversion to digital signal are typically performed on the top chip. The bottom processing chip typically performs downstream processing of the digital signals received from the image sensor chip. Among the various processing functions that may be performed are, for example, color derivation, data compression, and conversion of data to standard graphics file formats for export to the device memory or other destinations external to the image sensor chip.

While some aspects of the circuitry on the processing chip may be standardized, these chips are generally customized and specifically designed for each particular image sensor. The chip layout design and the development of fabrication schemes required for the manufacture of prior art chips are significant undertakings and are generally very expensive. This high non-recurring engineering cost presents a significant barrier to the development of chips performing new processing schemes, for example specialty image sensors for small markets. Accordingly, there is a need in the art for simplified means of producing customized image sensors.

The present invention fulfills the unmet need in the art for affordable and facile image sensor customization. The image sensors of the invention comprise reconfigurable components that can be programmed and customized to perform a very broad set of operations. These novel image sensors and associated methods provide the art with a means of obtaining a customizable image sensor without the substantial non-recurring engineering costs encountered using current technologies. In the semiconductor business model, the production cost per part is highly dependent on the total manufacturing volume of the part and tends to go down with higher manufacturing volumes. The methods of the invention allow a single image sensor to be utilized in a variety of applications, significantly reducing the cost per part.

### BRIEF DESCRIPTION OF THE DRAWING

FIG. 1 is an exploded view of the two wafers of a stacked image sensor chip of the invention.

### DETAILED DESCRIPTION OF THE INVENTION

The invention is directed to image sensors comprising at least two layers, the two layers being stacked and bonded to create a functional image sensor. The top layer will be referred to herein as the top chip or imaging chip. This top chip is stacked atop one or more lower layers comprising processing chips. For convenience, the description herein will be directed to a two-layer image sensor, wherein a single processing chip, referred to as the bottom chip is stacked below the imaging chip. However, it will be understood that the various components and functions of the bottom chip can be implemented on multiple stacked processing chips, for example, two, three, or four processing chips.

The description of the invention provided herein will make reference to various components, such as “memory components” or “ADC components.” It will be understood that each such component may be comprised of multiple elements which enable its function. For example, the ADC component of a processor chip may comprise multiple elements such as comparators, amplifiers, and capacitors.

A major aspect of the invention is the use of one or more configurable components in the processor chip. “Configurable,” as used herein, refers to the ability of a component to be programmed or otherwise set up or commanded to function in two or more alternate operational modes. Configuration may be performed via the I/O interfaces residing on the processing chip, or by other external data transmission components. Configurable components may comprise one-time programmable processor technologies. Alternatively, the configurable component may comprise as a fully programmable processor technology. Fully programmable processors are generally preferred in most implementations, as these allow for updates and upgrades to the components or system to be implemented. The programmable components allow a single chip design to serve multiple input, processing, and output operations, allowing novel chip designs to be tested and applied without the usual prohibitory up-front costs of developing a custom chip.

The Imaging Chip. The top layer of the stacked image sensors of the invention is the imaging chip. This chip comprises an array of pixels. The pixels comprise the standard components of a CMOS image sensor including a photodiode, transistors and other components for integrating charge, charge readout, and reset. Components for correlated double sampling can also be included. The top chip will also comprise control signal lines and buses for directing operation of the imaging chip and readout of signals from each pixel.

The photodiode of the imaging chip pixels may be of any type known in the art. The selection of photodiode type will depend on the specific applications for which the sensor is designed. The optimal substrate materials and processing methods will depend on the type of photodiode selected, as known in the art. Any photodiode type known in the art may be employed in the practice of the invention. For example, a P-well/n-substrate may be utilized. The photodiodes of the invention may also comprise N-well/p-substrate designs, as known in the art. P-N, P-I-N, avalanche photodiodes, reverse avalanche photodiodes may also be used. The use of pinned photodiodes is preferred. Non-silicon photodiode materials, for example gallium arsenide (GaAs), Indium gallium arsenide, or germanium may also be used to the extent that they are compatible with wafer level processing or integration with silicon wafers and to the extent that they may be efficiently bonded with silicon wafers.

The pixel designs may be of any type known in the art. For example, 3T designs, 4T designs, global shutter designs, and pixels having hybrid global shutter/rolling shutter functions, as known in the art, may be used.

It will be understood that the pixel array of the top imaging chip may be overlaid by any number of various filters (e.g. Bayer arrays) or microlens assemblies, as known in the art.

In one implementation, the control lines that direct operation of the imaging chip are connected to components of the bottom processing chip, such that the bottom processing chip can operate the pixels of the top imaging chip. In an alternative embodiment, the control lines are operated independently of the bottom processing chip, however this implementation does not allow customized operation of the top chip by the configurable components of the processing chip.

In one implementation, the imaging chip comprises analog-to-digital conversion (ADC) components, such that signals from the individual pixels can be converted to digital signals on the top imaging chip. These digital signals can be routed by vias or other stacked wafer interconnects to the processing components of the bottom processing wafer for storage and further operations. In an alternative embodiment, the analog outputs from the pixel array are stored in an array of sample-and-hold circuits residing on the top chip, the outputs of which can be routed, by vias or other stacked wafer interconnects, to the bottom processing wafer for conversion to digital signals by ADC components present on the bottom processing wafer.

The Processing Chip. The bottom processing chip comprises any number of components, as described next.

Configurable Signal Receiving and Initial Processing Components. Components on the bottom chip receive and perform initial processing of analog or digital pixel readout signals from the top chip. The signal receiving and initial processing components may be programmable, configurable circuitry that is used to receive and format pixel readout data from the top image sensor chip for subsequent processing. Advantageously, a customizable signal receiving and initial processing means can be used to accept a range of readout speeds and a to accommodate a wide range of signal output formats.

In one embodiment, the top imaging wafer comprises a series of sample-and-hold circuits, these being in connection series of ADC components on the bottom processing wafer and which convert the analog signals from the top wafer pixels to digital signals. Generally, in this configuration, to avoid noise, parasitic capacitance, and other data quality issues, it will be optimal that the ADC components of the bottom chip be stacked directly below the sample-and-hold components of the top wafer, such that the length of the signal path between them is minimized.

Memory Components. The processing chip also comprises one or more memory components, wherein signal data can be stored prior to, during, or after signal processing. Any suitable memory module known in the art may be used. SRAM, RAM, DRAM, mixtures thereof, and other memory types known in the art can be used. The one or more memory elements serve the other components of the processor chip by providing transient data storage, buffering, and other functions where memory means are required. The memory means are optionally configurable for efficient interfacing with other components.

Configurable Image Sensor Control Components. Some implementations of the invention comprise image sensor control components residing on the bottom processing chip. This configurable element or group of elements can be programmed to drive the operation of the image sensor in any desired mode, frame rate, readout scheme, etc., limited only by the innate abilities of the pixel design in the overlaying image sensor chip. The image sensor control means can drive clocks, control signals (e.g. opening and closing of gates), and readout bus selection, among other functions normally encompassed in the operation of image sensing chips. Image sensor control components are connected to the upper imaging sensor chip by control lines which deliver signals to the upper chip.

The image sensor control functions can be implemented by one or more configurable microcontrollers. The microcontrollers may be of any type known in the art.

Configurable Signal Processing Components. The bottom processing chip comprises one or more configurable processors that can be programed to perform any number of logic or computational operations. These components allow customizable signal processing. General purpose processor modules may be used, preferably of sufficient size, speed, and power to effectively perform a wide range of complex operations. These custom processor components may be used for any number of standard and non-standard data processing steps, as described below. The custom processor means may optionally employ field-programmable gate array technologies known in the art, or similar technologies which enable broad customization of processor function. The signal processing components may also comprise one or more embedded systems for the efficient performance of common image data processing functions.

Configurable I/O. The bottom processor chip comprises one or more configurable I/O components. The configurable I/O components enable efficient communication and interfacing with the device in which the imaging module resides.

The configurable I/O components allow for inputs to the processor chip. Exemplary inputs include programming instructions for configuring the components of the image sensor. Configuration of image sensor operations can be input, and updates to previously installed programming can be readily delivered. Commands to switch image sensor operational modes can also be input via the I/O interface.

The configurable I/O components also enable efficient output of processed image data to the external memory or device in which the image sensor resides, enabling utilization of a wide range of signal outputs from the image sensing chip.

The I/O may perform “handshake” operations, perform data format conversion operations, perform channel selection, and other standard I/O functions. The configurable I/O preferably encompasses sufficient hardware elements and processing power and versatility to perform operations across a wide range of output data formats and interfaces. For example, the configurable I/O means may be compatible with various system interfaces, including: network connections (e.g. Ethernet, Wi-Fi, Bluetooth, etc.); memory standards (e.g. DDR3, DDR4); external processors (e.g. MIPI, XAUI); and output formats (e.g. PCIe, USB, CameraLink, etc).

Wafer Materials and Processing. The distribution of imaging and signal processing components on different chips provides advantages in manufacturing and performance. This allows for optimized substrate material selection and processing techniques for the components of each wafer, avoiding compromises in sensor performance and alleviating the need for complicated fabrication schemes that result when all components of a pixel and associated signal processing components are required to use a single fabrication process regime. For example, pixels can be made using substrates, tools, processing methods, and rules which are optimal for the creation of high-quality photodiodes. For example, the top wafer may be fabricated using elemental silicon and may be made using 180 nm processing. The bottom processing wafer may be fabricated using materials, rules, and processes optimized for high-performance devices, for example being fabricated using 65 nm processing.

Arrangements of the Components. The invention is not limited to any specific combination or arrangement of the various components. Within the processor chip, the size, distribution, and design of each component may be selected to effect any desired range of capabilities. It will be understood that each component may be present as a singular component or as multiple or distributed components.

The alignment, bonding, and interconnection of the top image sensor chip and underlying processor chip may be accomplished by any means known in the art for stacking multiple wafers, for example by bump bonding, direct wafer bonding, thermocompressive bonding, adhesive bonding, etc. Through-silicon vias, and other interconnects known in the art may be employed to connect top wafer and bottom wafer components.

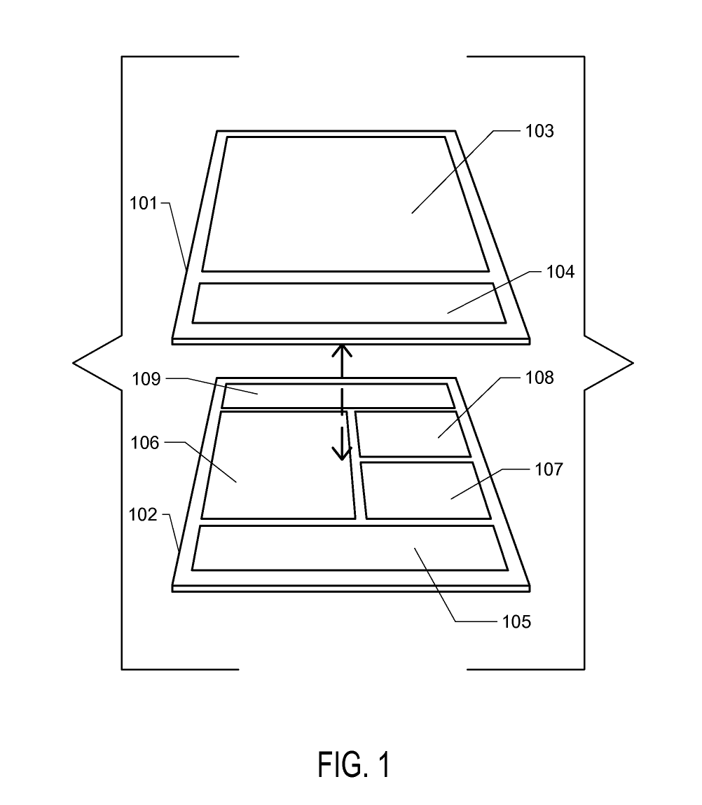

An exemplary embodiment of the invention is depicted in FIG. 1, which is an exploded view of a stacked image sensor assembly. In this implementation, the stacked image sensor comprises a top imaging chip (101) and a single bottom processing chip (102). The imaging chip comprises an array of pixels (103) and a series of sample-and-hold circuits (104) which receive and store pixel signal outputs. Configurable signal receiving and initial processing components (e.g. ADC components) (105) reside on the bottom processing wafer directly below the sample-and-hold circuits of the top wafer. The bottom signal processing wafer also comprises a configurable memory component (107), a configurable signal processing component (106), a configurable microcontroller (108) and a configurable I/O series of components (109).

### Operation of the Configurable Processor Chip

Advantageously, the use of a multiple configurable components enables fully customized operation of the image sensor chip, allowing the user to implement operations that optimize noise reduction, control power consumption, or adapt the image sensor for specific conditions. For example, in high speed photography or for extending dynamic range, operation of the image sensor chip at high frame rates is desirable. Conversely, if low power consumption is a desired feature, the image sensor chip may be configured to run at lower frame rates or with readout schemes that reduce power consumption. These competing performance objectives can be balanced as desired with the programmable image sensors of the invention.

The programmable processor is versatile and able to perform any number of data processing functions. Exemplary processing capabilities include color derivation, noise cancellation, tone mapping, image artifact rectification, data compression, etc. Advantageously, these operations can be customized as desired, allowing users to implement specific needs, or enabling providers with unique capabilities to make their technology available without manufacturing a custom chip. Exemplary specialized functions include WRGB or other irregular color processing, gesture recognition, facial recognition or other biometric functions, event detection, high dynamic range implementation, rolling shutter artifact correction, data reduction or compression schemes, and any number of other image data processing steps known in the art.

The image sensor chips can be programmed to operate in a single mode, or may be programmed to dynamically switch between two or more operational modes. For example, different modes may be enabled by manual selections made by users. Alternatively, automated switching between modes may be performed based on external conditions or stimuli (e.g. low light, camera movement, etc.), for example as detected by the signal processing functions of the processing chip or in response to inputs from components external to the stacked image sensor (e.g. light meters, gyroscopes, etc).

The scope of the invention further encompasses methods of using the stacked image sensors disclosed herein. In one embodiment, the methods of the invention comprise the initial programming of the configurable components of the stacked image sensor. In another embodiment, the methods of the invention comprise reprogramming, updating, or upgrading of a previously configured stacked image sensor of the invention.

Image sensor ADC elements currently in use may be configured in numerous ways. For example single slope, successive approximation, pipeline, flash, and folding ADC's all use comparators, amplifiers, and capacitors in various proportions and numbers. Each such fixed configuration will have unique properties, and performance characteristics will represent trade-offs in conversion rate, noise, and power consumption.

The reconfigurable image sensors of the invention may encompass general purpose ADC's having sufficient numbers of comparators, amplifiers, and capactiors as well as configurability of these elements such that they may be configured in various ways, for example in two or more ADC modes known in the art, including for example, two or more modes selected from the group consisting of the following: single slope, successive approximation, pipeline, flash, and folding ADC's. It is understood that image sensor control elements, memory elements, and processor elements are also configurable as necessary to enact and support the various ADC modes.

Configurability of ADC elements in the reconfigurable image sensors of the invention allows a single image sensor type to operate in a variety of modes. For example, using column parallel ADC's for image sensors is advantageous for high resolution arrays, because the data from an entire row of pixels is converted simultaneously. In contrast, higher frame rates can be achieved by reducing the number of rows (vertical resolution), but it's not possible to increase frame rate by reducing the number of columns (horizontal resolution). Utilizing the methods of the invention, a column parallel ADC can be reconfigured to utilize a smaller number of higher speed, serial ADC's for lower resolution, obtaining significantly higher frame rate when both vertical and horizontal resolutions are reduced.

Flexibility in the configuration of ADC's and supporting components allows for operation of a single image sensor in multiple modes. For example, the sensor can be configured for regular picture or video capture (in high resolution configuration), but can then be reconfigured to a low-resolution, high-speed sensr, for example, for iris recognition (for biometric applications) in the same camera.

In one embodiment, the column parallel ADC's can be slower single slope or dual slope ADC's, as known in the art. Each such ADC configuration would utilize one comparator. These comparators could alternatively be reconfigured to make a “flash” ADC that uses many comparators (8-bit flash ADC uses 256 comparators—generally N-bit flash uses 2̂N comparators) that is much faster than a single slope and can accept data from fewer columns as well as rows.

Conversely, if lower noise or bit-resolution is required, the single slope ADC's can be reconfigured to an over-sampling (or sigma-delta) ADC that uses one comparator per ADC. However, the over-sampling ADC uses a significant amount of digital processing (decimation) during the conversion. If the digital circuits are made from configurable digital processing blocks, they can be reconfigured to change the ADC type.

In general, digital processing is an important part of modern ADC's and reconfigurable processing allows enhancement and modification of the ADC's for each configuration.

The disclosed embodiments are presented for purposes of illustration and not limitation. While the invention has been described with reference to the described embodiments thereof, it will be appreciated by those of skill in the art that modifications can be made to the structure and elements of the invention without departing from the spirit and scope of the invention as a whole.

What is claimed is:

1. A stacked image sensor, comprising
a top imaging chip comprising:
an array of pixels; sample-and-hold circuits which receive and store pixel output signals from the pixel array; and
interconnects which connect the sample-and-hold circuits to ADC elements on the bottom wafer; and
a bottom processing chip comprising:
ADC elements which are connected by interconnects to the sample-and-hold circuits of the top chip;
one or more memory elements;
one or more signal processing elements;
one or more control elements; and
one or more I/O elements,
wherein at least one of the one or more ADC elements, the one or more memory elements, the one or more signal processing elements, the one or more control elements, or the one or more I/O elements is configurable.

2. The stacked image sensor chip of claim 1, wherein
the one or more control elements comprises an FPGA.

3. The stacked image sensor chip of claim 1, wherein
the one or more signal processing elements comprises an FPGA.

4. The stacked image sensor chip of claim 1, wherein
the image sensor may be reconfigured to perform in two or more distinct operational modes.

5. The stacked image sensor of claim 4, wherein
the two or more distinct operational modes comprise different frame rates, resolution, or power consumption characteristics.

6. The stacked image sensor of claim 4, wherein
the two or more distinct operational modes comprise a high-resolution mode for general photography or video capture and a high-speed mode for biometric applications.

7. The image sensor of claim 4, wherein
the two or more distinct operational modes comprise modes having different vertical resolution.

8. The image sensor of claim 4, wherein
the two or more distinct operational modes comprise modes having different horizontal resolution.

9. The stacked image sensor of claim 1, wherein
the ADC elements comprise sufficient numbers of amplifiers, comparators, and capacitors such that they may be configured in two more distinct operational modes.

10. The stacked image sensor of claim 9, wherein
the two or more ADC operational modes are selected from the group consisting of the following: single slope ADC mode, successive approximation ADC mode, pipeline ADC, flash ADC mode, and folding ADC mode.
